(19) United States
(12) Patent Application Publication
(10) Pub. No.: US 2017/0338359 A1
(43) Pub. Date: Nov. 23, 2017

(54) SUBTRACTIVE HINGE AND ASSOCIATED METHODS

(71) Applicant: Ascent Solar Technologies, Inc., Thornton, CO (US)

(72) Inventor: Jason Michael Messing, Denver, CO (US)

(21) Appl. No.: 15/673,283

(22) Filed: Aug. 9, 2017

Related U.S. Application Data
(62) Division of application No. 13/783,336, filed on Mar. 3, 2013, now abandoned.
(60) Provisional application No. 61/606,431, filed on Mar. 4, 2012.

(51) Int. Cl. H01L 31/04; H01L 31/046; H02S 30/20; H01L 31/048

(52) U.S. Cl. CPC H01L 31/04; H01L 31/048; H01L 31/046; H02S 30/20; Y02E 10/50

(57) ABSTRACT

An assembly includes first and second sections and a subtractive hinge coupling the first and second sections. The subtractive hinges forms at least one aperture. A method for forming a flexible photovoltaic assembly includes the following steps: (1) disposing a plurality of photovoltaic devices on a flexible backing material, such that the plurality of photovoltaic devices are divided between at least first and second sections, and (2) forming at least one aperture in the flexible backing material between the first and second sections.

### RELATED APPLICATIONS

This application is a divisional of U.S. patent application Ser. No. 13/783,336 filed Mar. 3, 2013, which claims benefit of priority to U.S. Provisional Patent Application Ser. No. 61/606,431 filed Mar. 4, 2012. Each of the above-mentioned applications is incorporated herein by reference.

### BACKGROUND

Hinges are commonly used in folding devices. For example, board games often include a playing board formed of several sections that are coupled by flexible hinges. The hinges allow the several playing board sections to be folded together for storage and transport. As another example, portable photovoltaic assemblies often include multiple photovoltaic sections coupled by hinges, such that the sections can be folded together for ease of transport and storage.

FIGS. 1-3 each show a prior art portable photovoltaic assembly 100 including multiple rigid photovoltaic sections 102 coupled by mechanical hinges 104. FIG. 1 shows photovoltaic device 100 completely unfolded, FIG. 2 shows device 100 partially folded, and FIG. 3 shows device 100 completely folded. Hinges 104 are rigid and have a pin, barrel, and wing construction, similar to conventional door or piano hinges. Sections 102 are relatively heavy and stiff, and device 102 therefore can be folded to follow its underlying topology to a limited extent, such as shown in FIG. 2. However, the size and configuration of hinges 104, as well as the relatively large thickness of photovoltaic sections 102, prevents device 100 from being folded flat for minimum stowage volume, as shown in FIG. 3. Additionally, hinges 104 are susceptible to damage by accidental impact and can be rendered useless if their pins are bent.

FIGS. 4-6 show another prior art photovoltaic assembly 400 including multiple flexible photovoltaic sections 402 coupled by flexible hinges 404. FIG. 4 shows device 400 unfolded and powering a cellular telephone 406. FIG. 5 shows a close up of two photovoltaic sections 402 joined by a respective flexible hinge 404, and FIG. 6 shows a portion of device 400 in a folded state.

Flexible hinges rely on a stiffness differential, i.e., the hinges being less stiff than adjacent sections, to direct bending and flexing to the hinges. Accordingly, photovoltaic sections 402 may include stiffeners so that sections 402 are stiffer than hinges 404. In some other instances, packaging of photovoltaic sections 402 is inherently stiff, such that photovoltaic sections 402 are stiffer than hinges 404, even without added stiffeners. Thus, photovoltaic assembly 400 is capable of bending along flexible hinges 404 to follow underlying topology with relative ease, as shown, for example, in FIG. 4. Additionally, flexible hinges 404 allow photovoltaic sections 402 to be bent at relatively sharp angles with respect to each, as shown, for example, in FIG. 6. However, the stiffeners in photovoltaic sections 402 and/or the inherent stiffness of photovoltaic section 402 packaging typically increases weight and thickness of sections 402, which is undesirable in many applications. Such relatively large thickness of photovoltaic sections 402 relative to flexible hinges 404 can be seen in FIG. 5.

FIGS. 7-10 show yet another prior art photovoltaic assembly 700 including multiple photovoltaic sections 702 coupled by flexible hinges 704 defined by creases in the assembly substrate. FIG. 7 shows assembly 700 completely folded for storage and transport, and FIGS. 8-10 show assembly 700 in its unfolded state.

Photovoltaic sections 702 include little to no appreciable stiffening elements. Thus, there is little difference in stiffness between photovoltaic sections 702 and flexible hinges 704. Such small stiffness differential between photovoltaic sections 702 and flexible hinges 704 can cause unreliable folding and unfolding. Additionally, the small stiffness differential can cause assembly 700 to not lay flat or to not follow its underlying topology very well, such as shown in FIGS. 8-10, thereby potentially causing the assembly to collect dust and/or water. Such folding and unfolding problems may be particularly acute in cold temperatures.

### SUMMARY

In an embodiment, an assembly includes first and second sections and a subtractive hinge coupling the first and second sections. The subtractive hinge forms at least one aperture.

In an embodiment, a photovoltaic assembly includes backing material and first, second, and third photovoltaic devices disposed on the backing material. The backing material forms at least one first aperture between the first and second photovoltaic devices to form a first subtractive hinge. The backing material further forms at least one second aperture between the second and third photovoltaic devices to form a second subtractive hinge.

In an embodiment, a method for forming a flexible photovoltaic assembly includes the following steps: (1) disposing a plurality of photovoltaic devices on a flexible backing material, such that the plurality of photovoltaic devices are divided between at least first and second sections, and (2) forming at least one aperture in the flexible backing material between the first and second sections.

### BRIEF DESCRIPTION OF THE DRAWINGS

FIGS. 1-3 show a prior art portable photovoltaic assembly.

FIGS. 4-6 show another prior art portable photovoltaic assembly.

FIGS. 7-10 show yet another prior art portable photovoltaic assembly.

FIG. 11 shows a top plan view of an assembly including a subtractive hinge forming two apertures, according to an embodiment.

FIG. 12 shows a top plan view of an assembly including a subtractive hinge forming three apertures, according to an embodiment.

FIG. 13 shows a top plan view of an assembly including a subtractive hinge forming four apertures, according to an embodiment.

FIG. 14 shows a top plan view of an assembly including a subtractive hinge forming seven apertures, according to an embodiment.

FIG. 15 shows a top plan view of an assembly including a subtractive hinge forming two oval-shaped apertures, according to an embodiment.

FIG. 16 shows a top plan view of an assembly including a subtractive hinge forming three oval-shaped apertures, according to an embodiment.

FIG. 17 shows a top plan view of an assembly including a subtractive hinge forming four oval-shaped apertures, according to an embodiment.

FIG. 18 shows a top plan view of another assembly including a subtractive hinge forming two oval-shaped apertures, according to an embodiment.

FIG. 19 shows a top plan view of another assembly including a subtractive hinge forming three oval-shaped apertures, according to an embodiment.

FIG. 20 shows a top plan view of another assembly including a subtractive hinge forming four oval-shaped apertures, according to an embodiment.

FIG. 21 shows a top plan view of another assembly including a subtractive hinge forming seven oval-shaped apertures, according to an embodiment.

FIG. 22-35 show one method of forming a photovoltaic assembly including subtractive hinges, according to an embodiment.

FIG. 36 shows a top plan view of an assembly including a subtractive hinge forming a single aperture, according to an embodiment.

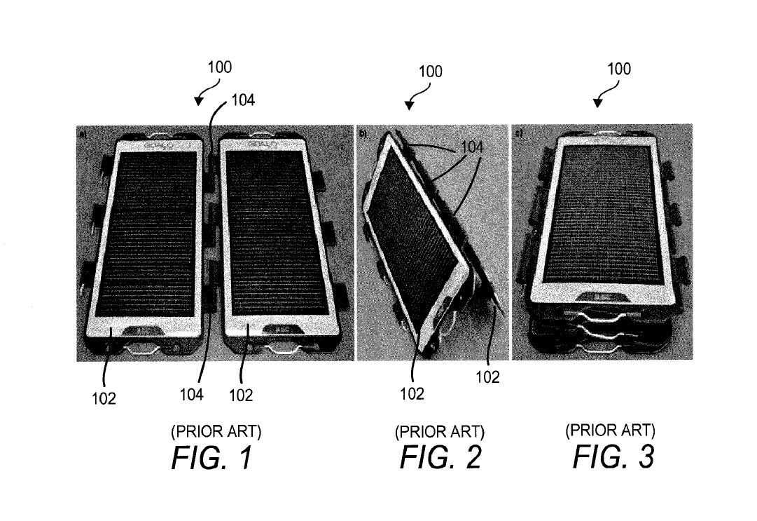

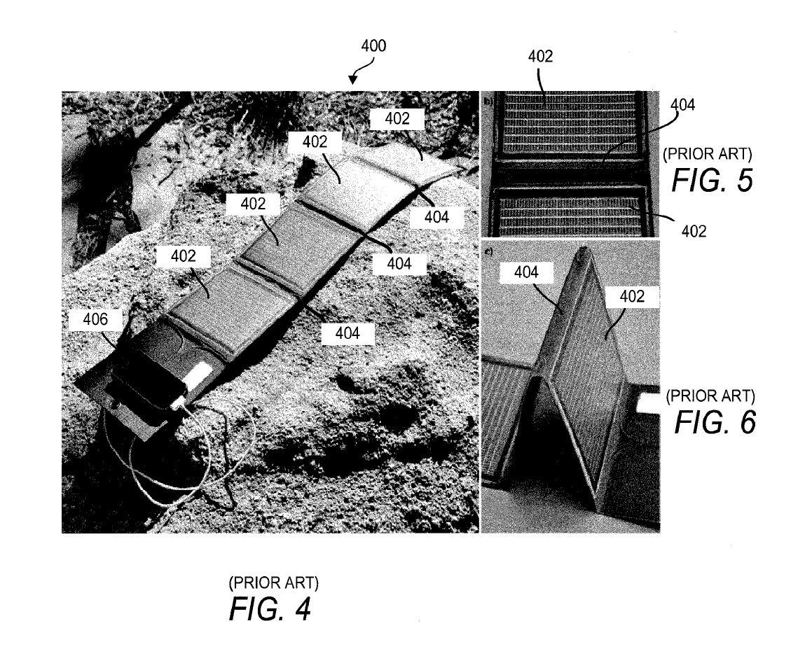

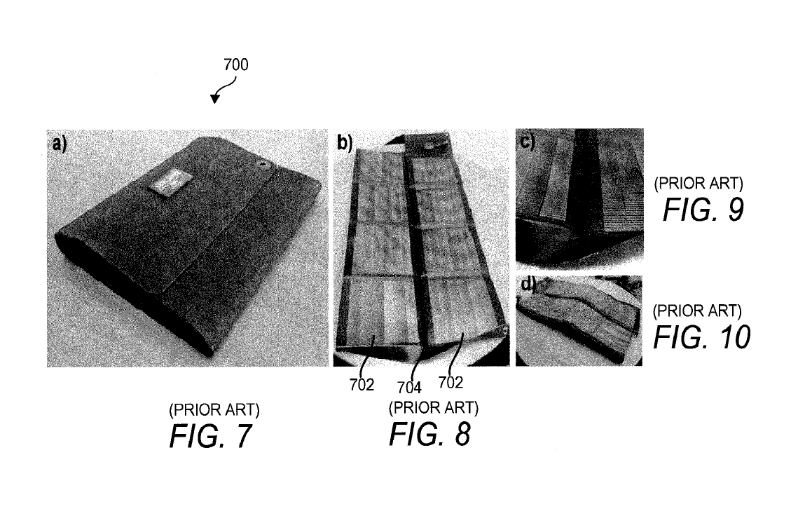

### DETAILED DESCRIPTION OF THE EMBODIMENTS

Applicant has discovered that stiffness differential in flexible hinges can be achieved by removing portions of the hinge material, instead of by adding stiffening material to the coupled sections. Such technique may advantageously allow a requisite stiffness differential to be achieved without a weight and size penalty associated with adding stiffening material. In fact, removing hinge material portions typically reduces assembly size and weight, which is highly desirable in many applications. Additionally, removing portions of hinge material reduces strain in the hinge, thereby promoting ease of folding and unfolding at the hinge, as well as small hinge profile when folded. Flexible hinges with portions removed may be referred to as “subtractive hinges” to denote that hinge material has been removed. The stiffness differential achieved by subtractive hinges also helps an assembly including the hinges to follow its surface topography.

Discussed below are several examples of subtractive hinges. It should be appreciated, though, that subtractive hinges are not limited to these particular examples, but may instead encompass other configurations without departing from the scope hereof.

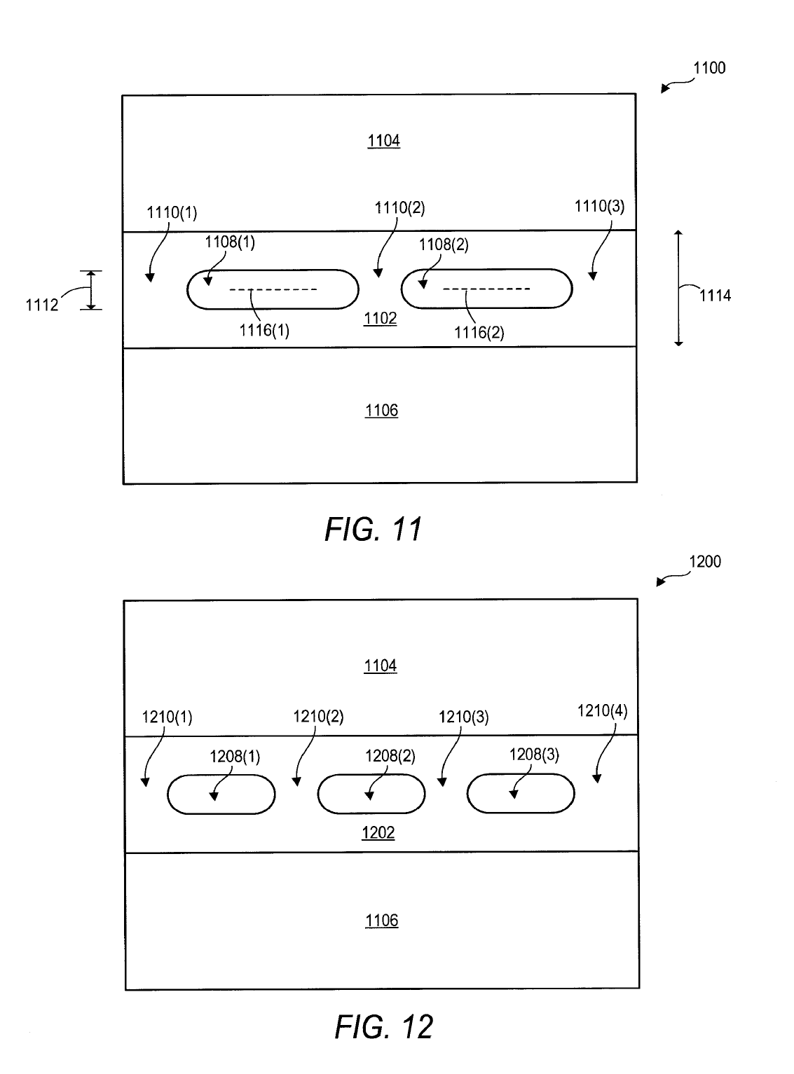

FIG. 11 shows a top plan view of an assembly 1100 including a subtractive hinge 1102 coupling adjacent sections 1104, 1106. While solid lines delineate sections 1104, 1106 from hinge 1102 to help a viewer distinguish these elements, the lines do not necessarily denote discontinuities. For example, in some embodiments, assembly 1100 is formed on a common backing or substrate of relatively flexible material, such as a polymer or a fabric material. In some other embodiments, subtractive hinge 1102 is formed of a different material than section 1104 and/or 1106. For example, in certain embodiments, subtractive hinge 1102 is formed of a relatively flexible material, while sections 1104, 1106 are formed of rigid materials.

Sections 1104, 1106 each optionally contain one or more components (not shown), such as photovoltaic devices, communication antennas, battery packs, and/or other electronic components. For example, in some embodiments, assembly 1100 is portable photovoltaic assembly where each section 1104, 1106 includes one or more flexible photovoltaic devices, such as photovoltaic modules or submodules. Such photovoltaic devices are, for example, multiple discrete or monolithically integrated photovoltaic devices, such as thin-film or crystalline photovoltaic devices. In certain of these embodiments, some or all of the assembly includes an optical protective overlay, encapsulants, and/or adhesives, such as discussed in the examples below.

Subtractive hinge 1102 forms two apertures 1108, which represent material removed from hinge 1102. In this disclosure, specific instances of an item may be referred to by use of a numeral in parentheses (e.g., aperture 1108(1)) while numerals without parentheses refer to any such item (e.g., apertures 1108). Apertures 1108 reduce the stiffness of hinge 1102 relative to sections 1104, 1106, thereby causing adjacent sections 1104, 1106 to be stiffer than hinge 1102. Such stiffness differential promotes bending of assembly 1100 along hinge 1102. The rounded sides of rectangular-shaped apertures 1108 reduce material stress when hinge 1102 is bended. The remaining portions of hinge 1102 form hinge elements 1110, which transfer stress between sections 1104, 1106. In certain embodiments, electrical conductors, such as bus bars in the form of conductive tape, cross subtractive hinge 1102 via at least one hinge element 1110. For example, a particular embodiment includes first and second photovoltaic devices disposed in first and second sections 1104, 1106, respectively. In this embodiment, bus bars cross hinge 1102 via one or more hinge elements 1110, to electrically couple the first and second photovoltaic devices. In some embodiments, hinge 1102 couples sections 1104, 1106 in a first direction 1114, and apertures 1108 have an elongated axis 1116 perpendicular to first direction 1114.

The number, size, and/or shape of apertures 1108 in subtractive hinge 1102 may be varied without departing from the scope hereof. For example, FIG. 12 shows a top plan view of an assembly 1200, which is similar to assembly 1100 (FIG. 11), but includes a subtractive hinge 1202 forming three apertures 1208, which are smaller than apertures 1108. Accordingly, subtractive hinge 1202 includes four hinge elements 1210, such that hinge 1202 is stiffer and stronger than hinge 1102, assuming all else is equal.

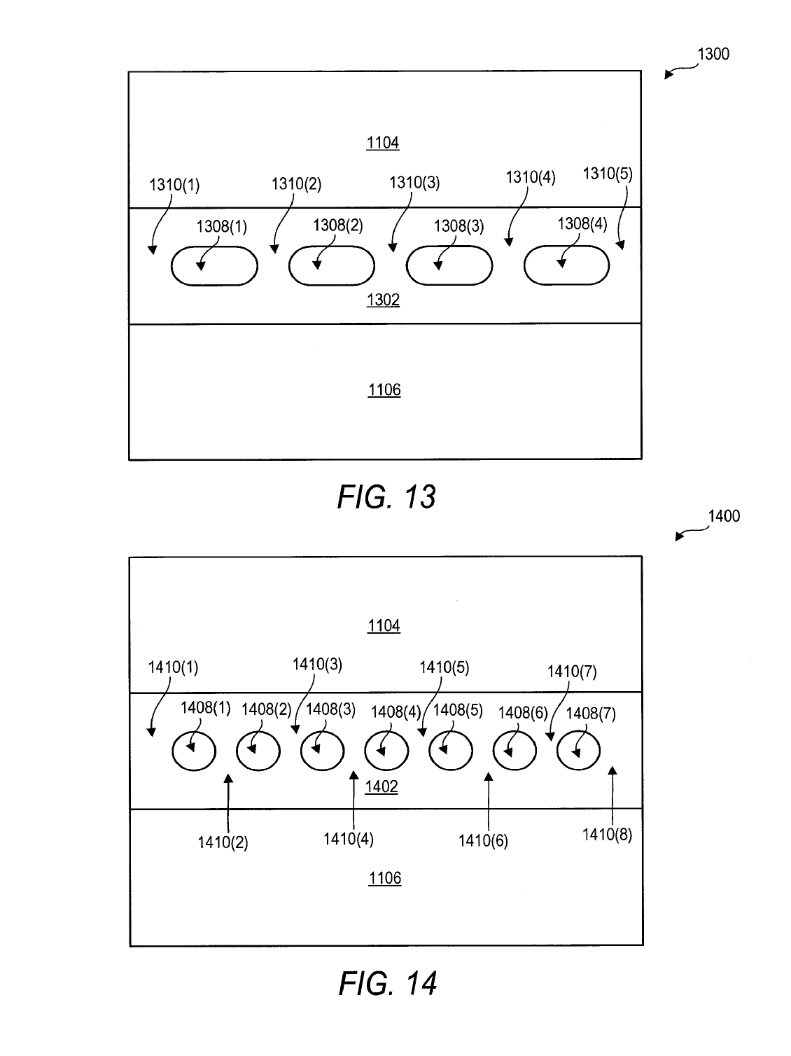

Similarly, FIGS. 13 and 14 respectively show top plan views of assemblies 1300 and 1400, which are similar to assemblies 1100 and 1200, but include subtractive hinges forming additional apertures. Specifically, assembly 1300 includes a subtractive hinge 1302 forming four apertures 1308, and assembly 1400 includes a subtractive hinge 1402 forming seven apertures 1408. Thus, subtractive hinge 1302 includes five hinge elements 1310, and subtractive hinge 1402 includes eight hinge elements 1410. Accordingly, hinge 1302 is stiffer and stronger than both of hinges 1102 and 1202, and hinge 1402 is stronger than each of hinges 1102, 1202, and 1302, assuming all else is equal.

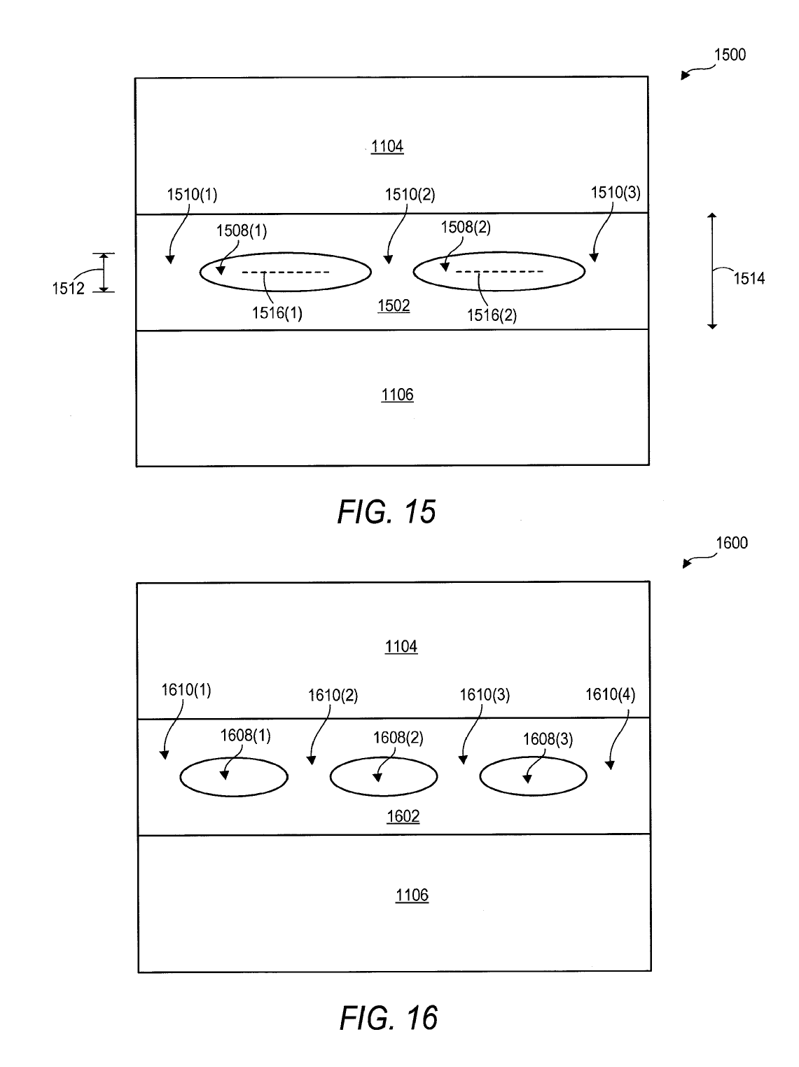

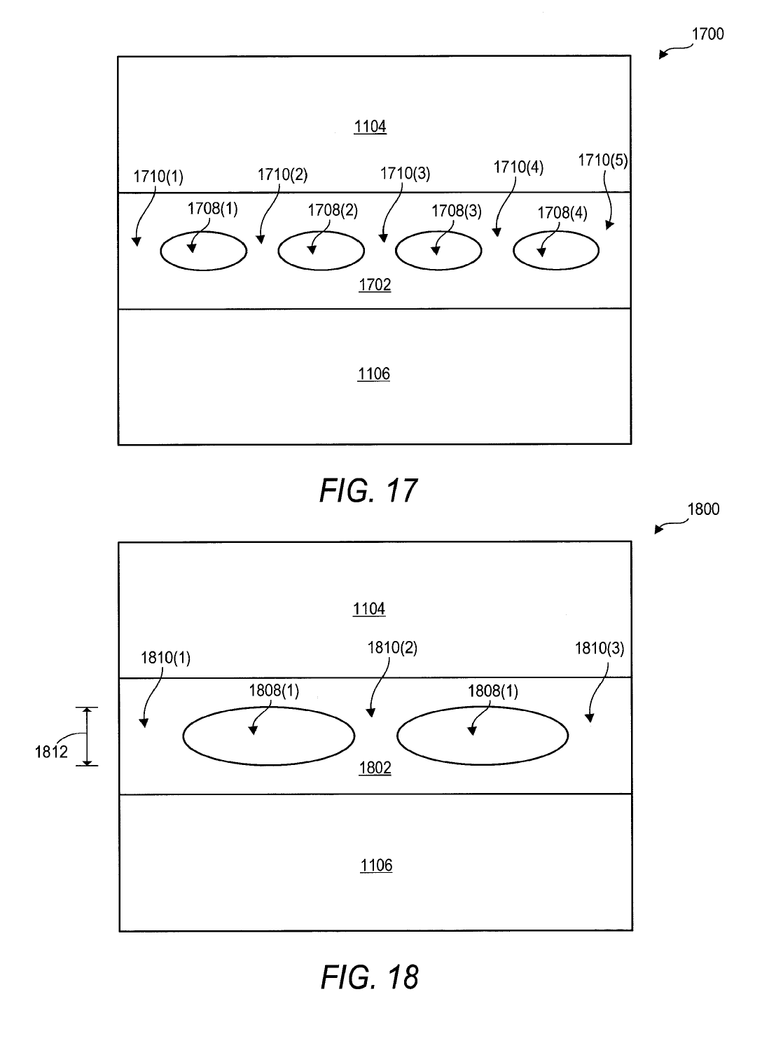

FIG. 15 shows a top plan view of an assembly 1500, which is similar to assembly 1100, but includes a subtractive hinge 1502 forming oval-shaped apertures 1508 instead of rectangular-shaped apertures with rounded sides. The oval-shaped apertures promote more focused bending with less potential for snagging or edge damage as compared to rectangular-shaped apertures. Height 1512 of apertures 1508 is equal to height 1112 of apertures 1108 (FIG. 11). Hinge 1502 includes three hinge elements 1510, which transfer stress between sections 1104, 1106. In some embodiments, hinge 1502 couples sections 1104, 1106 in a first direction 1514, and apertures 1508 have an elongated axis 1516 perpendicular to first direction 1514. FIGS. 16 and 17 show top plan views of assemblies 1600 and 1700, which are similar to assembly 1500, but respectively include subtractive hinges 1602 and 1702 in place of hinge 1502. Subtractive hinge 1602 forms three oval-shaped apertures 1608 and four hinge elements 1610, and subtractive hinge 1702 forms four oval-shaped apertures 1708 and five hinge elements 1710. Thus, hinge 1602 is stiffer and stronger than hinge 1502, and hinge 1702 is stronger and stiffer than both of hinges 1502 and 1602, assuming all else is equal.

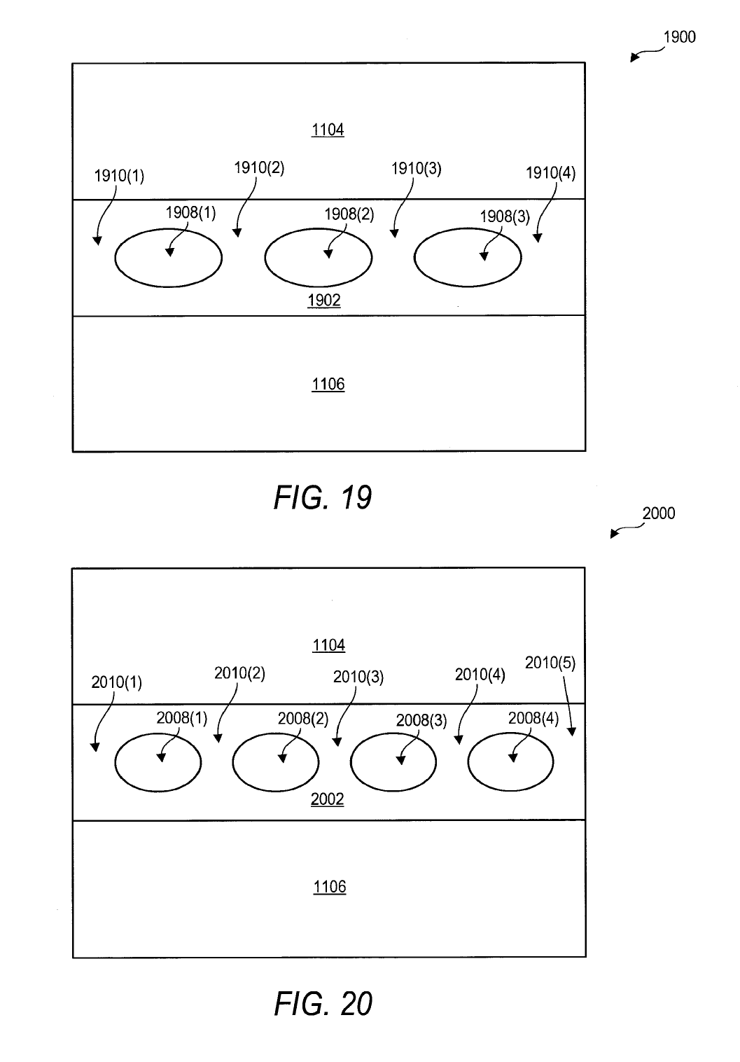

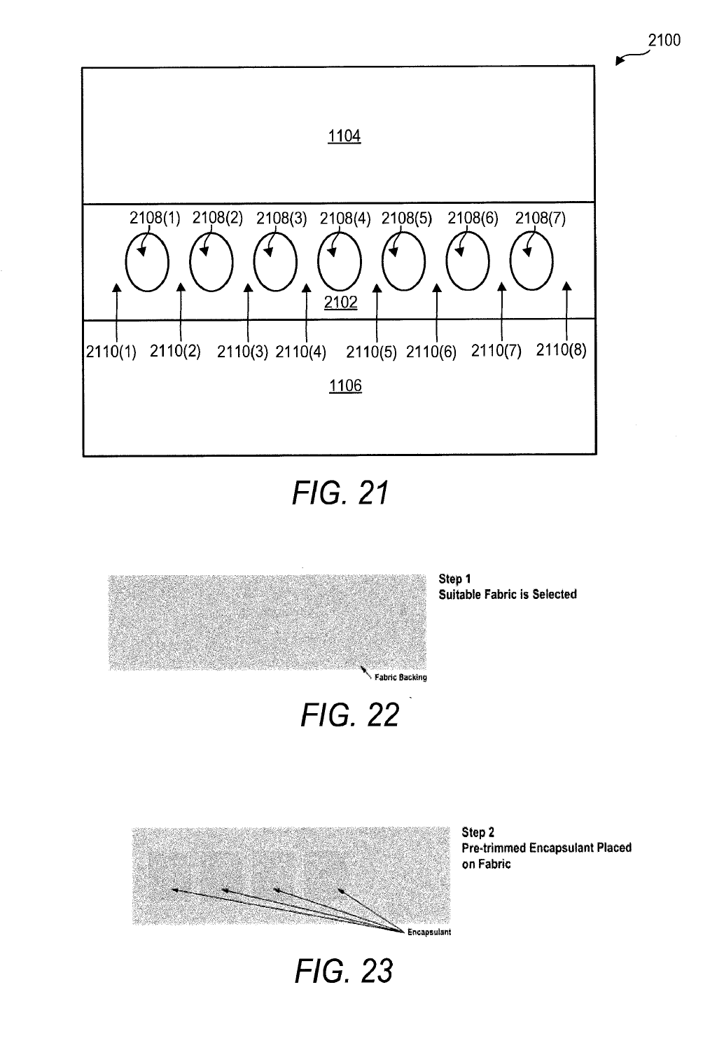

FIG. 18 shows a top plan view of assembly 1800, which is similar to assembly 1500, but includes subtractive hinge 1802 in place of subtractive hinge 1502. Hinge 1802 includes two oval-shaped apertures 1808, which are similar to apertures 1508 (FIG. 15). However, height 1812 of apertures 1808 is greater than height 1512 of apertures 1508. Such relatively large aperture height 1812 promotes folding in embodiments where sections 1104, 1106 have a relatively large thickness. Hinge 1802 includes three hinge elements 1810, which transfer stress between sections 1104, 1106. FIGS. 19, 20, and 21 show top plan views of assemblies 1900, 2000, and 2100, which are similar to assembly 1800, but respectively include subtractive hinges 1902, 2002, and 2102 in place of hinge 1802. Subtractive hinge 1902 forms three oval-shaped apertures 1908 and four hinge elements 1910, subtractive hinge 2002 forms four oval-shaped apertures 2008 and five hinge elements 2010, and subtractive hinge 2102 forms seven oval-shaped apertures 2108 and eight hinge elements 2110. Thus, hinge 1902 is stiffer and stronger than hinge 1802, hinge 2002 is stronger and stiffer than both of hinges 1802 and 1902, and hinge 2102 is stronger and stiffer than each of hinges 1802, 1902, and 2002, assuming all else is equal.

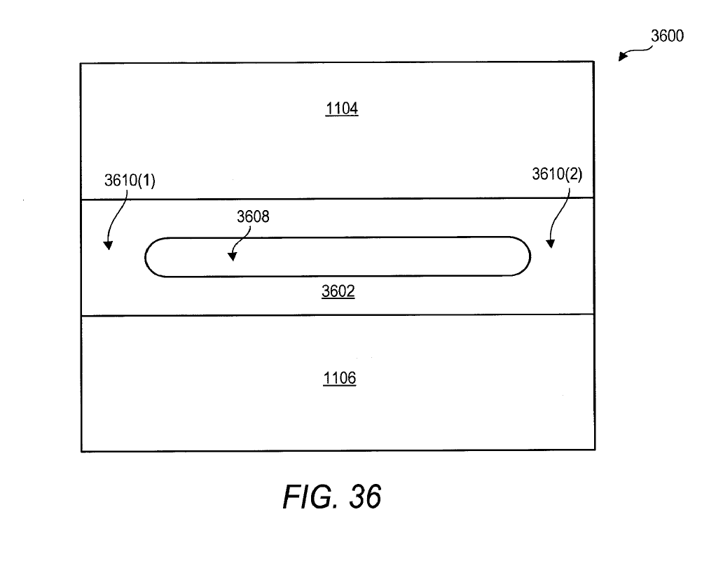

In some embodiments, the subtractive hinge forms only a single aperture. For example, FIG. 36 shows a top plan view of an assembly 3600, which is similar to assembly 1100 (FIG. 11), but includes a subtractive hinge 3602 forming a single aperture 3608, which is larger than each aperture 1108. Accordingly, subtractive hinge 3602 includes only two hinge elements 3610. Thus, hinge 3602 is lighter than hinge 1102, assuming all else is equal. However, hinge 1202 is not as stiff or as strong as hinge 1102, assuming otherwise identical assembly construction. Aperture 3608 could alternately be oval-shaped instead of rectangular-shaped with rounded sides.

Multiple subtractive hinges may be used to couple three or more sections. For example, assembly 1100 (FIG. 11) could be modified to include a second subtractive hinge (not shown) coupling a third section (not shown) to section 1106.

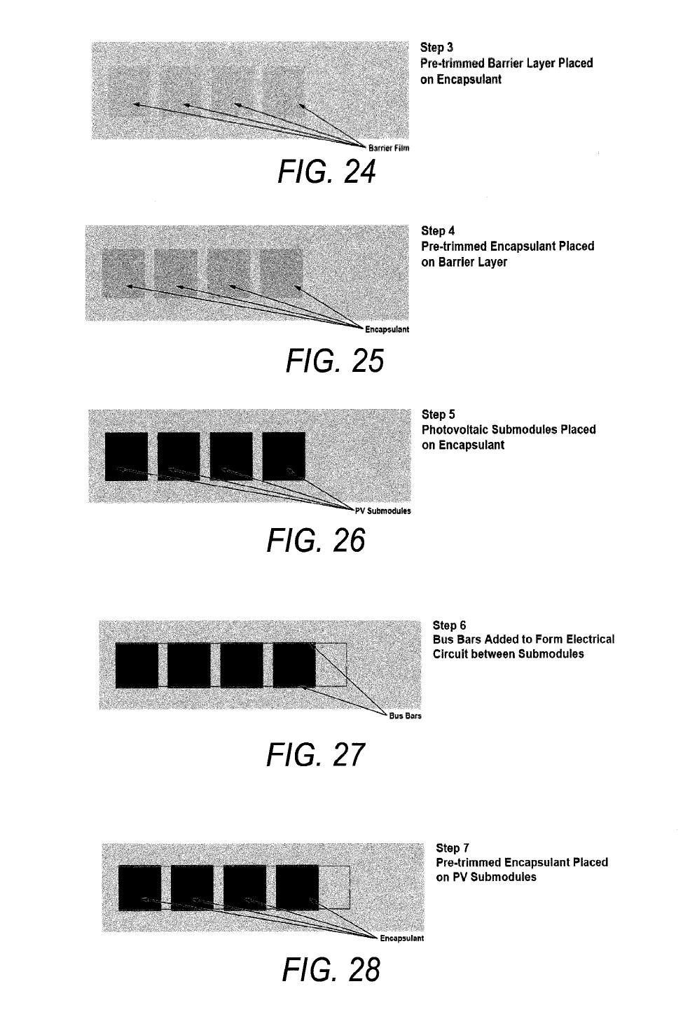

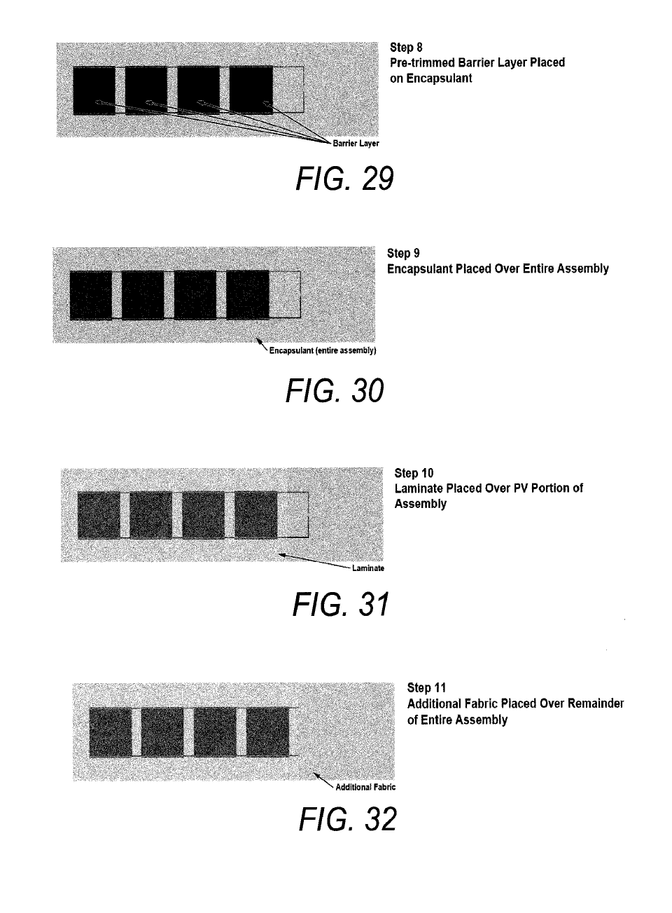

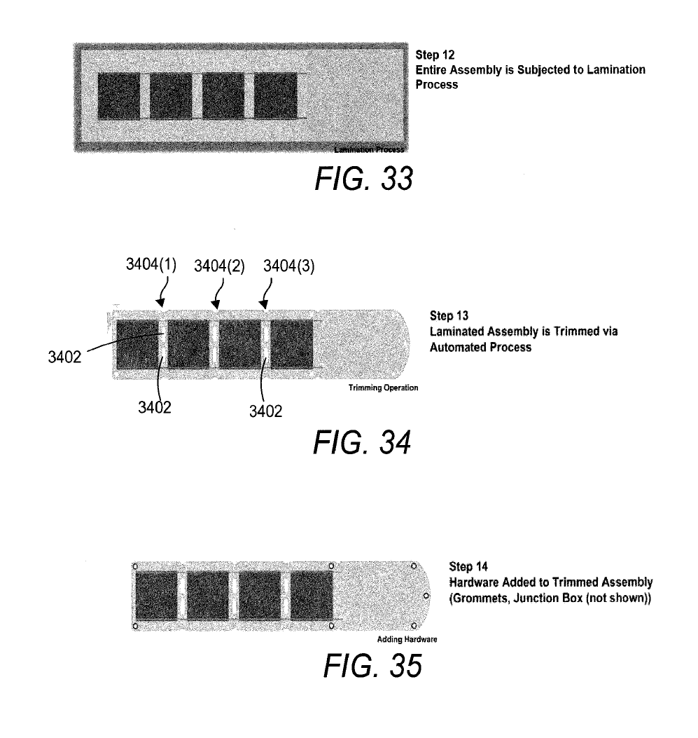

FIGS. 22-35 show one method of forming a photovoltaic assembly including subtractive hinges. FIG. 22 shows step 1 where a suitable fabric backing is selected. In step 2, as shown in FIG. 23, pre-trimmed encapsulant is placed on the backing material. In step 3, a pre-trimmed barrier layer is placed on the encapsulant, as shown in FIG. 24. In step 4, encapsulant is placed on the barrier layer, as shown in FIG. 25. In step 5, photovoltaic submodules are placed on encapsulant, as shown in FIG. 26. FIG. 27 shows step 6, where bus bars are added to form electrical circuit connections between the submodules. In step 7, as shown in FIG. 28, pre-trimmed encapsulant is placed on the submodules. In step 8, pre-trimmed barrier layer is placed on the encapsulant, as shown in FIG. 29. FIG. 30 shows step 9, where encapsulant is placed over the entire assembly, and FIG. 31 shows step 10, where laminate is placed over the photovoltaic portion of the assembly. In step 11, additional fabric is placed over the remainder of the assembly, as shown in FIG. 32. In step 12, the entire assembly is laminated, as shown as in FIG. 33. In step 13, the laminated assembly is trimmed, such as by an automated process, as shown in FIG. 34. Apertures 3402 are formed in the fabric backing in step 13 to create subtractive hinges 3404. Only some of apertures 3402 are labeled to promote illustrative clarity. The size, shape, and/or number of apertures 3402 may be varied without departing from the scope hereof. For example, the shape of apertures 3402 may be changed from rectangular-shape with rounded sides to oval-shaped. In step 14, hardware is added to the trimmed assembly, as shown in FIG. 35. Some examples of possible hardware include, but are not limited to, grommets and one or more junction boxes.

The following are examples of folding apparatuses including one or more subtractive hinges, such as one or more of the subtractive hinges discussed above. It should be understood, though, that the subtractive hinges disclosed herein are not limited to use in the apparatuses of the following examples.

(A1) A folding apparatus may include a flexible backing material, one or more flexible photovoltaic sections, optical protective overlay, encapsulant/adhesives, and one or more flexible hinges between adjacent photovoltaic sections to enable folding.

(A2) In the folding apparatus denoted as (A1), the flexible backing material may include fabric and/or reinforced plastic.

(A3) In either of the folding apparatuses denoted as (A1) or (A2), the one or more flexible photovoltaic sections may be flexible photovoltaic modules.

(A4) In the folding apparatus denoted as (A3), the flexible photovoltaic modules may include monolithically integrated thin film devices.

(A5) In the folding apparatus denoted as (A4), the flexible photovoltaic modules may include an interconnected string of discrete solar cells.

(A6) In the folding apparatus denoted as (A5), the interconnected string of discrete solar cells may include flexible discrete thin film solar cells.

(A7) In the folding apparatus denoted as (A5), the interconnected string of discrete solar cells may include flexible discrete crystalline solar cells.

(A8) In any of the folding apparatuses denoted as (A1) through (A7), one or more of the photovoltaic sections may be individually packaged.

(A9) In any of the folding apparatuses denoted as (A1) through (A8), the overlay may include one or more layers of protective films.

(A10) In the folding apparatus denoted as (A9), the one or more layers of protective films may include one or more protective laminates.

(A11) In either of the folding apparatuses denoted as (A9) or (A10), the one or more layers of protective films may include one or more barriers layers, such as to protect against moisture and/or air ingress.

(A12) In any of the folding apparatuses denoted as (A9) through (A11), the one or more layers of protective films may include an outer layer including an anti-glare and/or anti-reflection coating.

(A13) In any of the folding apparatuses denoted as (A9) through (A12), the overlay may be placed at least on the photovoltaic side of the device, and the overlay may cover the entire device.

(A14) In any of the folding apparatuses denoted as (A1) through (A13), the overlay may include one or more layers of encapsulants and/or adhesives.

(A15) In the folding apparatus denoted as (A14), the encapsulants and/or adhesives may provide mechanical, electrical, and/or environmental protection to the assembly of components.

(A16) In any of the folding apparatuses denoted as (A1) through (A15), the final assembly of components may be assembled in the following sequence: (1) flexible backing material, (2) requisite adhesive/encapsulant, (3) photovoltaic circuit, (4) requisite adhesive/encapsulant, (5) barrier layer, (6) requisite adhesive/encapsulant, and (7) top protective film.

(A17) In any of the folding apparatuses denoted as (A1) through (A16), adjacent photovoltaic sections may be connected into a circuit by a flat flexible wire lead tape across the subtractive hinge.

(A18) In the folding apparatus denoted as (A17), the circuit connections between by adjacent photovoltaic sections may series and/or parallel in nature.

(A19) In any of the folding apparatuses denoted as (A1) through (A18), the assembly may provide sufficient stiffness to protect the photovoltaic sections and circuit from mechanical damage.

(A20) In any of the folding apparatuses denoted as (A1) through (A19), the entire assembly of components may be integrated into the final assembly in a single curing step.

(A21) In any of the folding apparatuses denoted as (A1) through (A20), adhesive and/or encapsulant may be cured by thermal and/or light induced energy.

(A22) In any of the folding apparatuses denoted as (A1) through (A21), hinge material may be the same or dissimilar to the flexible backing material.

(A23) In any of the folding apparatuses denoted as (A1) through (A22), folding function of the photovoltaic system may be facilitated by greater stiffness in the adjacent photovoltaic sections compared to the interconnecting hinge.

(A24) In any of the folding apparatuses denoted as (A1) through (A23), discrepancy in stiffness between photovoltaic sections and hinges may be facilitated by subtracting material in the hinge area.

(A25) In the folding apparatus denoted as (A24), the number and shape of the subtracted region of the hinge may result in two or more contiguous stress paths between adjacent photovoltaic sections.

(A26) In the folding apparatus denoted as (A25), the strength of contiguous stress paths may be sufficient for required structural integrity between photovoltaic sections.

(A27) In either of the folding apparatuses denoted as (A25) or (A26), the width and number of subtracted regions may be sufficient to determine the amount of stress required in the contiguous stress paths to generate desired hinge flexibility.

(A28) In any of the folding apparatuses denoted as (A25) through (A27), the shape of the subtracted region may be sufficient to prevent the amount of stress required in the contiguous stress paths exceeding the failure stress of the hinge material.

(A29) In any of the folding apparatuses denoted as (A25) through (A28), the height of the subtracted region may be determined by the desired thickness of the folded material in the hinge that will be enclosed.

(A30) In any of the folding apparatuses denoted as (A25) through (A29), the subtracted region may be facilitated by mechanical cutting or stamping after the product is assembled

(A31) In any of the folding apparatuses denoted as (A25) through (A30), the subtractive hinges may be created after the assembly is completed.

(A32) In any of the folding apparatuses denoted as (A25) through (A31), the bending stiffness of the subtractive hinge area may be less than the resulting stiffness of the assembled stack adjacent to the hinge to facilitate predictable flexing in this area.

(A33) In any of the folding apparatuses denoted as (A25) through (A32), the subtractive process may include mechanical cutting, stamping, and/or laser trimming.

(A34) In any of the folding apparatuses denoted as (A25) through (A33), fabric edges may be heat treated to reduce the possibility of fraying or delimitation.

Combinations of Features

Features described above as well as those claimed below may be combined in various ways without departing from the scope hereof. The following examples illustrate some possible combinations:

(B1) An assembly may include first and second sections and a subtractive hinge coupling the first and second sections. The subtractive hinge may form at least one aperture.

(B2) In the assembly denoted as (B1), the first section may include a first photovoltaic device, and the second section may include a second photovoltaic device. The first and second photovoltaic devices may each include a plurality of monolithically integrated photovoltaic cells. The assembly may further include at least one bus bar crossing the subtractive hinge to electrically couple the first and second photovoltaic devices.

(B3) In either of the assemblies denoted as (B1) or (B2), the subtractive hinge may form at least one aperture having a rounded rectangular-shape.

(B4) In either of the assemblies denoted as (B1) or (B2), the subtractive hinge may form at least one aperture having an oval-shape.

(B5) In any of the assemblies denoted as (B1) through (B4), the subtractive hinge may couple the first and second sections in a first direction, and the at least one aperture may include an aperture having an elongated axis perpendicular to the first direction.

(B6) Any of assemblies denoted as (B1) through (B5) may further include a common backing selected from the group consisting of a fabric material and a polymer material, the first and second photovoltaic devices may be disposed on the common backing, and the at least one aperture may extend through at least the common backing.

(B7) The assembly denoted as (B6) may further include first, second, third, and fourth encapsulant layers. The first photovoltaic device may be disposed between the first and second encapsulant layers, and the second photovoltaic device may be disposed between the third and fourth encapsulant layers.

(B8) The assembly denoted as (B7) may further include: (1) first, second, third, and fourth barrier layers, and (2) fifth, sixth, and seventh, encapsulant layers. The first barrier layer may be disposed between the first and fifth encapsulant layers. The second barrier layer may be disposed between the third and sixth encapsulant layers. The third barrier layer may be disposed between the second and seventh encapsulant layers. The fourth barrier layer may be disposed between the fourth and seventh encapsulant layers.

(B9) The assembly denoted as (B8) may further include a first laminate layer disposed on the seventh encapsulant layer, opposite to the first and second photovoltaic devices.

(B10) The assembly denoted as (B9) may further include an additional fabric layer disposed on the first laminate layer, opposite to the seventh encapsulant layer.

(B11) In any of the assemblies denoted as (B1) through (B10), the subtractive hinge may form a plurality of apertures.

(B12) In any of assemblies denoted as (B1) through (B11), a stiffness of the subtractive hinge may be less than a stiffness of the first section and less than a stiffness of the second section.

(C1) A method for forming a flexible photovoltaic assembly may include the following steps: (1) disposing a plurality of photovoltaic devices on a flexible backing material, such that the plurality of photovoltaic devices are divided between at least first and second sections; and (2) forming at least one aperture in the flexible backing material between the first and second sections.

(C2) The method denoted as (C1) may further include laminating the plurality of photovoltaic devices and the flexible backing material prior to the step of forming at least one aperture.

(C3) The method denoted as (C2) may further include sandwiching the plurality of photovoltaic devices between encapsulant and barrier layers prior to the step of laminating.

(C4) In any of the methods denoted as (C1) through (C3), the step of forming at least one aperture may include forming at least one aperture having a rectangular-shape with rounded sides.

(C5) In any of the methods denoted as (C1) through (C3), the step of forming at least one aperture may include forming at least one aperture having an oval-shape.

(C6) In any of the methods denoted as (C1) through (C5), the step of forming at least one aperture may include forming a plurality of apertures between the first and second sections.

Changes may be made in the above methods and systems without departing from the scope hereof. For example, although many of the assembly examples discussed above show two sections coupled a subtractive hinge, the examples can be modified to include additional sections coupled by additional subtractive hinges. Therefore, the matter contained in the above description and shown in the accompanying drawings should be interpreted as illustrative and not in a limiting sense. The following claims are intended to cover generic and specific features described herein, as well as all statements of the scope of the present method and system, which, as a matter of language, might be said to fall therebetween.

What is claimed is:

1. A method for forming a flexible photovoltaic assembly, comprising:
disposing a plurality of photovoltaic devices on a flexible backing material, such that the plurality of photovoltaic devices are divided between at least first and second sections; and
forming at least one aperture in the flexible backing material between the first and second sections.

2. The method of claim 1, further comprising laminating the plurality of photovoltaic devices and the flexible backing material prior to the step of forming at least one aperture.

3. The method of claim 2, further comprising sandwiching the plurality of photovoltaic devices between encapsulant and barrier layers prior to the step of laminating.

4. The method of claim 1, the step of forming at least one aperture comprising forming at least one aperture having a rectangular-shape with rounded sides.

5. The method of claim 1, the step of forming at least one aperture comprising forming at least one aperture having an oval-shape.

6. The method of claim 1, the step of forming at least one aperture comprising
forming a plurality of apertures between the first and second sections.
